(19) United States
(12) Patent Application Publication
(10) Pub. No.: US 2024/0321711 A1
(43) Pub. Date: Sep. 26, 2024

(54) SUBSTRATE AND A METHOD FOR MANUFACTURING THE SAME

(71) Applicant: Chengdu Monolithic Power Systems Co., Ltd., Chengdu (CN)

(72) Inventors: Yingjiang Pu, Chengdu (CN); Hang Jiang, Saratoga, CA (US)

(21) Appl. No.: 18/606,035

(22) Filed: Mar. 15, 2024

(30) Foreign Application Priority Data
Mar. 20, 2023 (CN) 202310274631.1

(51) Int. Cl. H01L 23/498; H01L 21/48; H05K 1/02; H05K 1/11; H05K 3/42

(52) U.S. Cl. CPC H01L 23/49838; H01L 21/4857; H01L 21/486; H01L 23/49822; H05K 1/0271; H05K 1/115; H05K 3/429; H05K 2201/09609; H05K 2201/09636

(57) ABSTRACT

A substrate includes a first dielectric layer having a first surface and a second surface. The first dielectric layer includes a plurality of first conductive vias and a plurality of second conductive vias. These two kinds of conductive vias are formed to penetrate the first dielectric layer and have different orientations for reduce warpage of the substrate.

### CROSS-REFERENCE TO RELATED APPLICATIONS

This application claims the benefit of CN application No. 202310274631.1 filed on Mar. 20, 2023 and incorporated herein by reference.

### TECHNICAL FIELD

Embodiments of the present invention relate to substrates that may be used for semiconductor device packaging, and more particularly but not exclusively, relate to substrates having conductive vias and a method for manufacturing the same.

### BACKGROUND OF THE INVENTION

A substrate may be used to carry various kinds of device and elements to form a semiconductor package in a form suitable for electronic products. These devices and elements may be attached to both sides of the substrate by some conductive structures, such as solder balls. However, there may be a warpage problem of the substrate. When the substrate fails to meet a desirable flatness, the conductive structures between the substrate and the devices and elements attached thereto may not be stable enough.

To reduce substrate warpage, solutions using auxiliary structures or new dielectric layer materials are proposed, but these solutions are not suitable for applications where strict requirement for reliability is needed.

Therefore, a substrate which can provide good flatness and improved conductivity is needed.

### SUMMARY OF THE INVENTION

Embodiments of the present invention are directed to a substrate for semiconductor package. The substrate may include at least a first dielectric layer having a first surface and a second surface. A plurality of first conductive vias and a plurality of second conductive vias are disposed in the first dielectric layer. Each of the plurality of first conductive vias and each of the plurality second conductive vias include a surface exposed on the first surface and a surface exposed on the second surface. As for each of the plurality of the first conductive vias, the size of surface exposed on the first surface is larger than size of surface exposed on the second surface. As for the each of the plurality of the second conductive vias, the size of surface exposed on the first surface is smaller than size of surface exposed on the second surface.

Embodiments of the present invention are directed to method for manufacture the substrate. The method may include a procedure of providing a first dielectric layer having first and second surfaces opposed to each other. A plurality of first through holes penetrating the first dielectric layer may be formed from the first surface, then the substrate may be flipped to keep the second surface upwards. After that, a plurality of second through holes penetrating the first dielectric layer may be formed from the second surface. The plurality of first through holes and the plurality of second through holes may be filled or coated to form a plurality of first conductive vias and a plurality of second conductive vias respectively. As described above, each of the plurality of first conductive vias and each of the plurality second conductive vias include a surface exposed on the first surface and a surface exposed on the second surface. As for each of the plurality of the first conductive vias, the size of surface exposed on the first surface is larger than size of surface exposed on the second surface. As for the each of the plurality of the second conductive vias, the size of surface exposed on the first surface is smaller than size of surface exposed on the second surface.

### BRIEF DESCRIPTION OF DRAWINGS

For a better understanding of the present disclosure, embodiments of the invention will be described in accordance with the following drawings, which are used for illustrative purpose only. The drawings illustrate only some of the features in an embodiment. It should be understood that the drawings are not necessarily to scale. Like elements are provided with like reference numerals in different appended drawings.

FIG. 1 is an exploded view illustrating a substrate 100 in accordance with an example embodiment of the present disclosure.

FIG. 2(a) is a top view illustrating a first dielectric layer 10A of the substrate 100 in accordance with an example embodiment of the present disclosure.

FIG. 2(b) is a top view illustrating the first dielectric layer 10A of the substrate 100 in accordance with another example embodiment of the present disclosure.

FIG. 2(c) is a top view illustrating the first dielectric layer 10A of the substrate 100 in accordance with another example embodiment of the present disclosure.

FIG. 3 is an exploded view illustrating a substrate 200 in accordance with an example embodiment of the present disclosure.

FIG. 4 is a top view illustrating the first dielectric layer 20A of the substrate 200 in accordance with an example embodiment of the present disclosure.

FIG. 5 is a flowchart of a method for manufacturing the substrate in accordance with one example embodiment of the present disclosure.

### DETAILED DESCRIPTION OF THE INVENTION

Detailed description of the embodiments is provided merely to give examples and not intended to be limiting. Plenty of details are provided to assist the reader in gaining a comprehensive understanding of the present invention. However, many other ways of implementing the disclosure of this application described herein will be apparent. Description of materials and methods that are known in the art may not be addressed in this disclosure for simplicity.

Throughout the specification and claims, the articles “a,” “an,” and “the” are intended to include the plural forms as well, unless the context clearly indicates otherwise. These phases “one embodiment”, “an embodiment”, “an example” and “examples” are not necessarily directed to the same embodiment or example. Furthermore, the features, structures, or characteristics may be combined in one or more embodiments or examples.

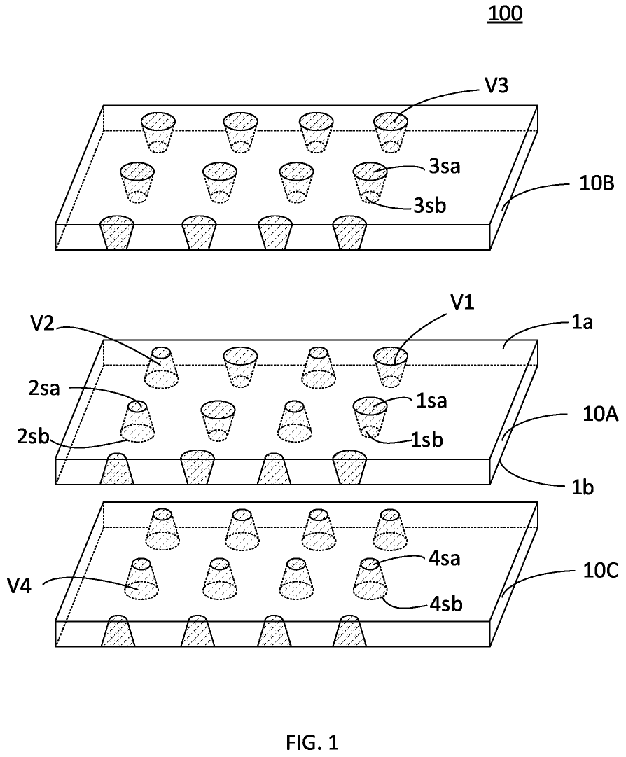

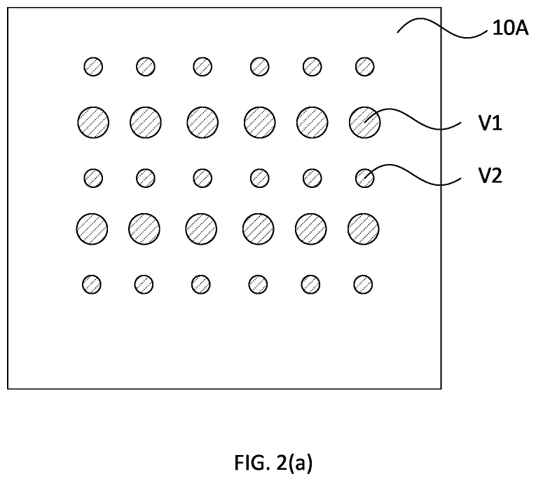

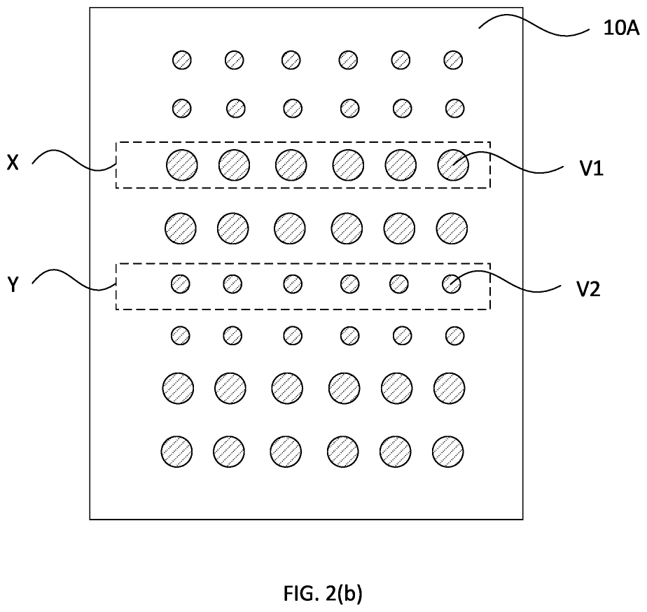

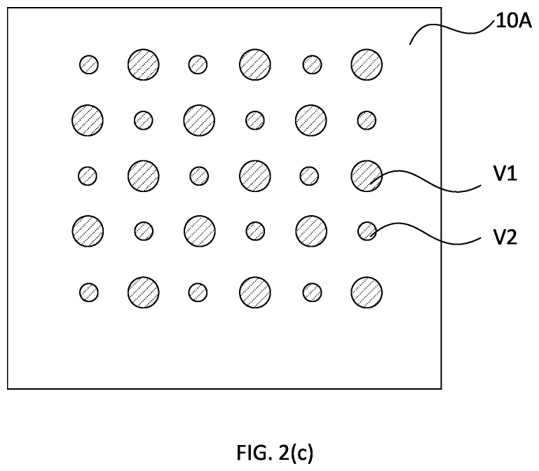

FIG. 1 is an exploded view illustrating a substrate 100 in accordance with an example embodiment. FIG. 2(a) is a top view illustrating a first dielectric layer 10A of the substrate 100 in accordance with an example embodiment.

Referring to FIG. 1, the substrate 100 may include a laminated substrate having three dielectric layers as an example. A first dielectric layer 10A having a first surface 1a and a second surface 1b. A second dielectric layer 10B may be arranged on the first surface 1a and a third dielectric layer 10C may be arranged on the second surface 1b. The substrate 100 may further include patterned conductive structures, such as redistribution layers disposed between the dielectric layers, which are all omitted in figures of this disclosure.

The substrate may further include two kinds of conductive vias with different orientations embedded in the first dielectric layer 10A: a plurality of first conductive vias V1 and a plurality of second conductive vias V2. These conductive vias penetrate the first dielectric layer 10A and expose from the first surface 1a and the second surface 1b. Each of the plurality of first conductive vias V1 includes a surface 1sa exposed on the first surface 1a and a surface 1sb exposed on the second surface 1b. A size of the surface 1sa is larger than that of the surface 1sb. Each of the plurality of second conductive vias V2 includes a surface 2sa exposed on the first surface 1a and a surface 2sb exposed on the second surface 1b. A size of the surface 2sa is smaller than that of the surface 2sb.

In some embodiments, when the first conductive vias V1 and the second conductive vias V2 are cut along several planes parallel to the first surface 1a, a size of cross sections of V1 may increase towards the first surface 1a while a size of the cross sections of V2 may increase towards the second surface 1b.

In some embodiments, when the first conductive vias V1 and the second conductive vias V2 are cut along several planes parallel to the first surface 1a, the size of cross sections of V1 may continually increase towards the first surface 1a while the size of the cross sections of V2 may continually increase towards the second surface 1b.

In some embodiments, when the first conductive vias V1 and the second conductive vias V2 are cut along several planes perpendicular to the first surface 1a, a cross section of each first conductive via V1 includes a gradually increasing width in a direction away from the second surface 1b, and a cross section of each second conductive via V2 includes a gradually increasing width in a direction away from the first surface 1a.

In some embodiments, when the first conductive vias V1 and the second conductive vias V2 are cut along several planes perpendicular to the first surface 1a, the cross section of each first conductive via V1 includes a continually increasing width in the direction away from the second surface 1b, and the cross section of each second conductive via V2 includes a continually increasing width in the direction away from the first surface 1a.

As illustrated in FIG. 1, the plurality of first conductive vias V1 are arranged in rows, which are parallel to the rows composed of the plurality of second conductive vias V2.

The substrate may further include a plurality of third conductive vias V3 embedded in the second dielectric layer 10B. The plurality of third conductive vias V3 penetrate the second dielectric layer 10B and expose from its surfaces. Each of the plurality of third conductive vias V3 includes a surface 3sa away from the first surface 1a and a surface 3sb close to the first surface 1a. The size of surface 3sa is larger than size of surface 3sb. The plurality of third conductive vias V3 are arranged correspondingly with the first conductive vias V1 or the second conductive vias V2 to provide an electrical path.

In some embodiments, when the plurality of third conductive vias V3 are cut along several planes parallel to the first surface 1a, a size of cross sections of each of the plurality of third conductive vias V3 may gradually decrease or continually decrease towards the first surface 1a.

In some embodiments, when the one of the plurality of third conductive vias V3 are cut along several planes perpendicular to the first surface 1a, a cross section of the third conductive via V3 includes a gradually increasing or a continually increasing width in the direction away from the first surface 1a.

The substrate may further include a plurality of fourth conductive vias V4 embedded in the third dielectric layer 10C. The plurality of fourth conductive vias V4 penetrate the third dielectric layer 10C and expose from its surfaces. Each of the plurality of fourth conductive vias V4 includes a surface 4sa close to the second surface 1b and a surface 4sb away from the second surface 1b. A size of surface 4sa is smaller than a size of surface 4sb. The plurality of fourth conductive vias V4 are arranged correspondingly with the first conductive vias V1 or the second conductive vias V2 to provide an electrical path.

In some embodiments, when the plurality of fourth conductive vias V4 are cut along several planes parallel to the first surface 1a, a size of cross sections of each of the plurality of fourth conductive vias V4 may gradually decrease or continually decrease towards the second surface 1b.

In some embodiments, when the plurality of fourth conductive vias V4 are cut along several planes perpendicular to the first surface 1a, a cross section of each fourth conductive vias V4 includes a gradually increasing or a continually increasing width in the direction away from the second surface 1b.

Referring to FIG. 2(b), the plurality of first conductive vias V1 are arranged in rows named X, the plurality of second conductive vias V2 are arranged in rows named Y, and the rows X and the rows Y are arranged in parallel. In some embodiments, the rows X and the rows Y are alternately arranged to form an XYXY layout as shown in FIG. 2(a), while they may have alternative layouts in other embodiments. Referring to FIG. 2(b), every two rows X and every two rows Y are alternately arranged to form an XXYYXXYY layout. Referring to FIG. 2c, the plurality of first conductive vias V1 and the plurality of second conductive vias V2 are arranged in a matrix, and the most closely adjacent positions of each first conductive vias V1 in the matrix is occupied by one second conductive via V2.

The warpage problem of a laminated substrate is strongly correlated with the degree of warpage of the first dielectric layer 10A. As shown in FIG. 2(a)-FIG. 2(c), the plurality of first conductive vias V1 and the plurality of second conductive vias V2 are arranged alternately in certain patterns to make the stress distribution of the first dielectric layer 10A relatively balanced, which can effectively reduce the degree of warpage of the first dielectric layer 10A. In some embodiments, the plurality of first conductive vias V1 and the plurality of second conductive vias V2 account for 50% respectively. In some other embodiments, the ratios between the plurality of conductive vias V1 and the plurality of second conductive vias V2 can be set accordingly as long as the purpose of reducing warpage can be achieved.

Since the two kinds of conductive vias V1 and V2 are non-uniform conductors in opposite orientations, by arranging them in the described manner can make the resistive distribution of the first dielectric layer more uniform. In addition, by arranging the two kinds of conductive vias V1 and V2 as described, these embodiments can provide a more compact layout compared with conventional solution, which allow more vias to be embedded in the dielectric layer. Therefore, the substrate disclosed in the present disclosure exhibits improved electrical conductivity as well. In some embodiments, those skilled in the art may dispose more layers to form the substrate 100. For example, dispose a fourth dielectric layer on the second dielectric layer 10B and dispose a fifth dielectric layer on the third dielectric layer 10C. In some embodiments, a plurality of conductive vias with one single orientation may be arranged in the fourth and fifth dielectric layers, just as the way the plurality of third conductive vias V3 disposing in the second dielectric layer 10B and the way the plurality of fourth conducive vias V4 disposing in the third dielectric layer 10C described above. Since the warpage of the first dielectric layer 10A is effectively reduced, the laminated substrate with multilayer dielectric layers formed by the additive process shows good flatness. Those skilled in the art may also form and use a substrate with only one dielectric layer, i.e., the first dielectric layer 10A according to this disclosure.

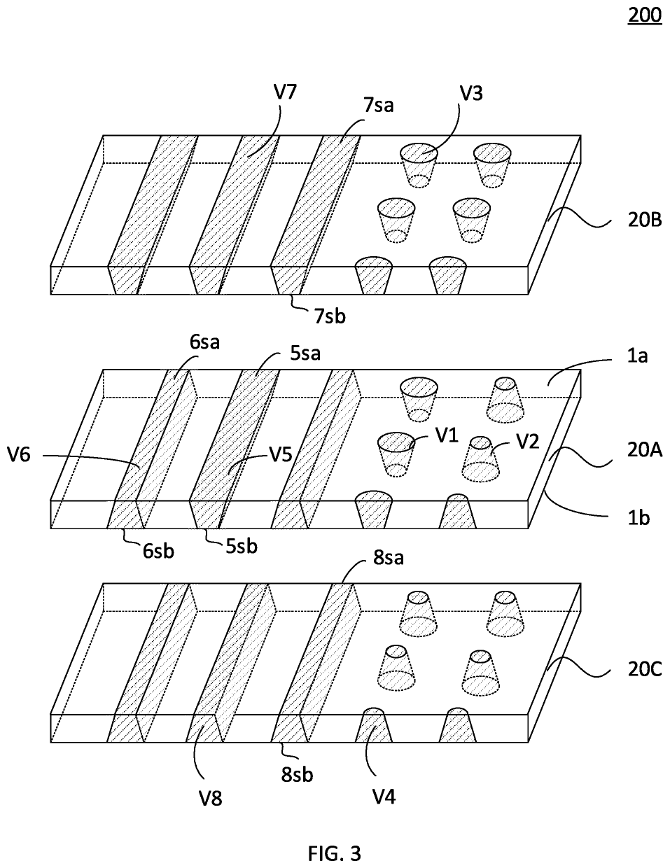

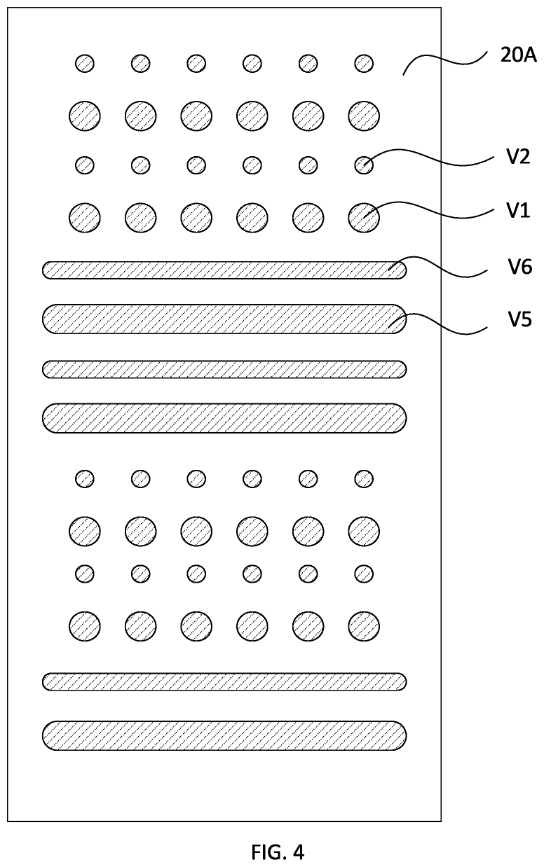

FIG. 3 is an exploded view illustrating a substrate 200 in accordance with an example embodiment. FIG. 4 is a top view illustrating a first dielectric layer 20A of the substrate 200 in accordance with an example embodiment.

Referring to FIG. 3, the substrate 200 is a laminated substrate having three dielectric layers. A first dielectric layer 20A having a first surface 1a and a second surface 1b. A second dielectric layer 20B may be arranged on the first surface 1a and a third dielectric layer 20C may be arranged on the second surface 1b. The substrate 200 may also include patterned conductive structures, such as redistribution layers, disposed between the dielectric layers, which are all omitted in figures of this disclosure.

Same elements in FIG. 1 are provided with same or like reference numerals in FIG. 3 and they may not be addressed here for simplicity. Compared with FIG. 1, the substrate 200 shown in FIG. 3 further include a plurality of fifth conductive vias V5 and a plurality of sixth conductive vias V6.

The plurality of fifth conductive vias V5 has the same orientation as the plurality of first conductive vias V1. More specifically, the plurality of fifth conductive vias V5 penetrate the first dielectric layer 20A and expose from the first surface 1a and the second surface 1b. Each of the plurality of fifth conductive vias V5 includes a surface 5sa exposed on the first surface 1a and a surface 5sb exposed on the second surface 1b. A size of the surface 5sa is larger than that of surface 5sb.

In some embodiments, when the plurality of fifth conductive vias V5 are cut along several planes parallel to the first surface 1a, a size of cross sections of V5 may gradually increase or continually increase towards the first surface 1a.

Each fifth conductive via V5 has a stronger capability of conducting current than each first conductive via V1. In some embodiments, the size of the surface 5sa is larger than the size of the surface 1sa, and the size of the surface 5sb is larger than the size of the surface 1sb. In some embodiments, when these vias are cut along a plane parallel to the first surface 1a, the size of the cross section of each fifth conductive via V5 is larger than that of the each first conductive via V1. In some other embodiments, when these vias are cut along any plane parallel to the first surface 1a, the size of the cross section of each fifth conductive via V5 is larger than that of the each first conductive via V1.

The plurality of six conductive vias V6 has the same orientation as the plurality of second conductive vias V2. More specifically, the plurality of sixth conductive vias V6 penetrate the first dielectric layer 20A and expose from the first surface 1a and the second surface 1b. Each of the plurality of sixth conductive vias V6 includes a surface 6sa exposed on the first surface 1a and a surface 6sb exposed on the second surface 1b. A size of the surface 6sa is smaller than that of the surface 6sb.

In some embodiments, when the plurality sixth conductive vias V6 are cut along several planes parallel to the first surface 1a, a size of cross sections of V6 may gradually increase or continually increase towards the second surface 1b.

Each sixth conductive via V6 has a stronger capability of conducting current than each second conductive via V2. In some embodiments, the size of the surface 6sa is larger than that of the surface 2sa, and the size of the surface 6sb is larger than the size of the surface 2sb. In some embodiments, when these vias are cut along a plane parallel to the first surface 1a, the size of the cross section of each sixth conductive via V6 is larger than that of the each second conductive via V2. In some other embodiments, when the vias are cut along any plane parallel to the first surface 1a, the size of the cross section of each sixth conductive via V6 is larger than that of the each second conductive via V2.

Referring to FIG. 3, only a portion of exposed surfaces of conductive vias V5 and V6 are shown, thus the exposed surfaces of each fifth conductive via V5 and sixth conductive via V6 may have rectangular like shape in FIG. 3. In some embodiments, the exposed surfaces of the fifth and the sixth conductive vias may have strip like shape as shown in FIG. 4, more specifically, rectangle with rounded corners. Referring to FIG. 4, in some embodiments, the strip like conductive vias V5 and V6 extend in a direction parallel to the rows of conductive vias V1 and V2 and the strip like conductive vias V5 and V6 are arranged alternately. Although the conductive vias V1 and V2 shown in FIG. 4 are arranged as the layout shown in FIG. 2(a), they may also be arranged as the layout shown in FIG. 2(b) or FIG. 2(c) in other embodiments.

The substrate may further include a plurality of seventh conductive vias V7 embedded in the second dielectric layer 10B. The plurality of seventh conductive vias V7 penetrate the second dielectric layer 10B and expose from its surfaces. Each of the plurality of seventh conductive vias V7 includes a surface 7sa away from the first surface 1a and a surface 7sb close to the first surface 1a. A size of surface 7sa is larger than a size of surface 7sb. The plurality of seventh conductive vias V7 are arranged correspondingly with the fifth conductive vias V5 or the sixth conductive vias V6 to provide an electrical path.

In some embodiments, when the plurality of seventh conductive vias V7 are cut along several planes parallel to the first surface 1a, a size of cross sections of V7 may gradually decrease or continually decrease towards the first surface 1a.

In some embodiments, when the plurality of seventh conductive vias V7 are cut along several planes perpendicular to the first surface 1a, a cross section of each seventh conductive vias V7 includes a gradually increasing or a continually increasing width in the direction away from the first surface 1a.

Each seventh conductive via V7 has a stronger capability of conducting current than each third conductive via V3. In some embodiments, the size of the surface 7sa is larger than that of the surface 3sa, and the size of the surface 7sb is larger than the size of the surface 3sb. In some embodiments, when these vias are cut along a plane parallel to the first surface 1a, the size of the cross section of each seventh conductive via V7 is larger than that of the each third conductive via V3. In some other embodiments, when the vias are cut along any plane parallel to the first surface 1a, the size of the cross section of each seventh conductive via V7 is larger than that of the each third conductive via V3.

The substrate may further include a plurality of eighth conductive vias V8 embedded in the third dielectric layer 10C. The plurality of eighth conductive vias V8 penetrate the third dielectric layer 10C and expose from its surfaces. Each of the plurality of eighth conductive vias V8 includes a surface 8sa close to the second surface 1b and a surface 8sb away from the second surface 1b. A size of surface 8sa is smaller than a size of surface 8sb. The plurality of eighth conductive vias V8 are arranged correspondingly with the fifth conductive vias V5 or the sixth conductive vias V6 to provide an electrical path.

In some embodiments, when the eighth conductive vias V8 are cut along several planes parallel to the first surface 1a, a size of cross sections of V8 may gradually decrease or continually decrease towards the second surface 1b.

In some embodiments, when the eighth conductive vias V8 are cut along several planes perpendicular to the first surface 1a, a cross section of each eighth conductive vias V8 includes a gradually increasing or a continually increasing width in the direction away from the second surface 1b.

Each eighth conductive via V8 has a stronger capability of conducting current than each fourth conductive via V4. In some embodiments, the size of the surface 8sa is larger than that of the surface 4sa, and the size of the surface 8sb is larger than the size of the surface 4sb. In some embodiments, when these vias are cut along a plane parallel to the first surface 1a, the size of the cross section of each eighth conductive via V8 is larger than that of the each fourth conductive via V4. In some other embodiments, when the vias are cut along any plane parallel to the first surface 1a, the size of the cross section of each eighth conductive via V8 is larger than that of the each fourth conductive via V4.

Referring to FIG. 3, there are at least two kinds of electric paths. One kind of electric path may include the third conductive vias V3, the first conductive vias V1/the second conductive V2 and the fourth conductive V4, another kind of electric path may include the seventh conductive vias V7, the fifth conductive vias V5/the sixth conductive vias V6 and the eighth conductive vias V8. The latter of the two has a stronger capability of conducting current and a better thermal performance.

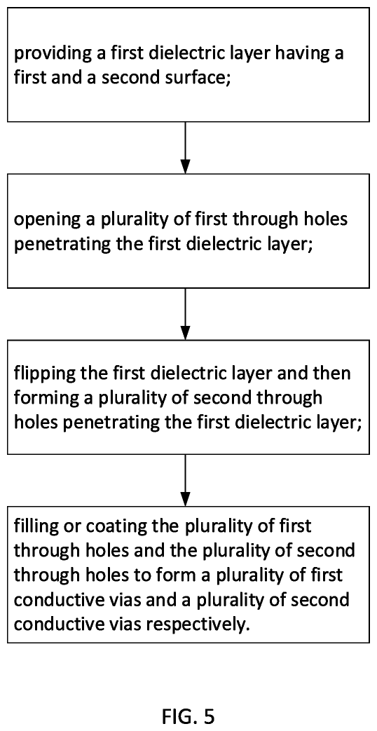

Embodiments of the present invention are also directed to a method for manufacturing the substrate. FIG. 5 schematically shows a flowchart of the method.

For example, a dielectric layer, such as partially cured resin or Ajinomoto Build-up Film (ABF), may be provided as the first dielectric layer 10A. A plurality of first through holes may be opened from the first surface 1a, then the first dielectric layer 10A may be flipped to keep its second surface 1b upwards and a plurality of second through holes may be opened from the second surface 1b.

The plurality of first through holes and the plurality of second through holes may be filled with or coated with conductive materials to become the first plurality of conductive vias V1 and the second plurality of conductive vias V2. Filling or coating process may be accomplished by electroplating or other process, the conductive material may be copper, nickel, gold, palladium, silver or alloys.

Redistribution layers may be formed on the first surface 1a and the second surface 1b, which is not described here in this disclosure for simplicity. Then the second dielectric layer 10B may be disposed on the first surface 1a, and at the same time, the third dielectric layer 10C may be disposed on the second surface 1B. A plurality of third through holes penetrating the second dielectric layer 10B may be formed, and at the same time, a plurality of fourth through holes penetrating the third dielectric layer 10C are formed. These through holes may be filled with or coated with conductive materials to form the third conductive vias V3 and the fourth conductive vias V4.

In some embodiments, to manufacture the substrate described with the reference of FIG. 3, a plurality of fifth through holes are formed in the procedure which the plurality of first through holes are formed, while a plurality of sixth through holes are formed in the procedure which the plurality of second through holes are formed. These through holes may be filled with or coated with conductive materials to form the fifth conductive vias V5 and the sixth conductive vias V6.

In some embodiments, to manufacture the substrate described with the reference of FIG. 3, a plurality of seventh through holes are formed in the procedure which the plurality of third through holes are formed, while a plurality of eighth through holes are formed in the procedure which the plurality of fourth through holes are formed. These through holes may be filled with or coated with conductive materials to become the plurality of seventh conductive vias V7 and the plurality of eighth conductive vias V8.

While some embodiments of the present invention have been described in detail above, it should be understood, of course, these embodiments are for exemplary illustration only and are not intended to limit the scope of the present invention. Various modifications are contemplated, and they obviously will be resorted to by those skilled in the art without departing from the spirit and the scope of the invention.

1. A substrate, comprising:
a first dielectric layer having a first surface and a second surface;
a plurality of first conductive vias penetrating the first dielectric layer, wherein each one of the plurality of first conductive vias has a surface exposed on the first surface and a surface exposed on the second surface, and wherein a size of the surface exposed on the first surface is larger than a size of the surface exposed on the second surface; and
a plurality of second conductive vias penetrating the first dielectric layer, wherein each one of the plurality of second conductive vias has a surface exposed on the first surface and a surface exposed on the second surface, and wherein a size of the surface exposed on the first surface is smaller than a size of the surface exposed on the second surface.

2. The substrate of claim 1, wherein the plurality of first conductive vias are arranged in rows X, and the plurality of second conductive vias are arranged in rows Y, and wherein the rows X and the rows Y are arranged in parallel.

3. The substrate of claim 2, wherein the rows X and the rows Y are alternately arranged to form an XYXY layout.

4. The substrate of claim 2, wherein every two rows X and every two rows Y are alternately arranged to form an XXYYXXYY layout.

5. The semiconductor substrate of claim 1, wherein the plurality of first conductive vias and the plurality of second conductive vias are arranged in a matrix, each most closely adjacent position to each one of the plurality of first conductive vias in the matrix is occupied by one of the plurality of second conductive vias.

6. The semiconductor substrate of claim 1, when the plurality of first conductive vias and the plurality of second conductive vias are cut along a plane perpendicular to the first surface, a cross section of each one of the plurality of first conductive vias has a gradually increasing width in a direction away from the second surface, and a cross section of each one of the plurality of second conductive vias has a gradually increasing width in a direction away from the first surface.

7. The substrate of claim 1, wherein the substrate further comprises:
a second dielectric layer disposed on the first surface of the first dielectric layer; and
a plurality of third conductive vias penetrating the second dielectric layer;
wherein the plurality of third conductive vias are arranged correspondingly with the first conductive vias or the second conductive vias to provide an electrical path, and wherein each one of the plurality of third conductive vias has a surface close to the first surface and a surface away from the first surface.

8. The substrate of claim 7, wherein as for each one of the plurality of third conductive vias, a size of the surface close to the first surface is smaller than a size of the surface away from the first surface.

9. The substrate of claim 1, wherein the substrate further comprises:
a third dielectric layer disposed on the second surface of the first dielectric layer; and
a plurality of fourth conductive vias penetrating the third dielectric layer;
wherein the plurality of fourth conductive vias are arranged correspondingly with the first conductive vias or the second conductive vias to provide an electrical path, and wherein each one of the plurality of fourth conductive vias has a surface close to the second surface and a surface away from the second surface.

10. The substrate of claim 9, wherein as for each one of the plurality of fourth conductive vias, a size of the surface close to the second surface is smaller than a size of the surface away from the second surface.

11. The substrate of claim 1, wherein the substrate further comprises:
a plurality of fifth conductive vias penetrating the first dielectric layer, each one of the plurality of fifth conductive via has a surface exposed on the first surface and a surface exposed on the second surface, wherein a size of the surface exposed on the first surface is larger than a size of the surface exposed on the second surface; and
a plurality of sixth conductive vias penetrating the first dielectric layer, each one of the plurality of sixth conductive vias has a surface exposed on the first surface and a surface exposed on the second surface, wherein a size of the surface exposed on the first surface is smaller than a size of the surface exposed on the second surface;
wherein the size of the surface of each one of the plurality of fifth conductive vias exposed on the first surface is larger than the size of the surface of each one of the plurality of first conductive vias exposed on the first surface, and the size of the surface of each one of the plurality of fifth conductive vias exposed on the second surface is larger than the size of the surface of each one of the plurality of first conductive vias exposed on the second surface; and
wherein the size of the surface of each one of the plurality of sixth conductive vias exposed on the first surface is larger than the size of the surface of each one of the plurality of second conductive via exposed on the first surface, and the size of the surface of each one of the plurality of sixth conductive vias exposed on the second surface is larger than the size of the surface of each one of the plurality of second conductive vias exposed on the second surface.

12. The semiconductor substrate of claim 11, wherein when being cut along a plane perpendicular to the first surface, a size of a cross section of each one of the plurality of fifth conductive vias is larger than a size of a cross section of each one of the plurality of first conductive vias, and a size of a cross section of each one of the plurality of sixth conductive vias is larger than a size of a cross section of each one of the plurality of second conductive vias.

13. The substrate of claim 11, wherein the substrate further comprises:
a second dielectric layer disposed on the first surface of the first dielectric layer;
a plurality of third conductive vias penetrating the second dielectric layer; and
a plurality of seventh conductive vias penetrating the second dielectric layer;
wherein the plurality of third conductive vias are arranged correspondingly with the first conductive vias or the second conductive vias to provide an electrical path, and wherein each one of the plurality of third conductive vias has a surface close to the first surface and a surface away from the first surface;
wherein the plurality of seventh conductive vias are arranged correspondingly with the plurality of fifth conductive vias or the plurality of six conductive vias to provide an electrical path, and wherein each one of the plurality of seventh conductive vias has a surface close to the first surface and a surface away from the first surface; and
wherein when being cutting along a plane perpendicular to the first surface, a size of a cross section of each one of the seventh conductive vias is larger than a size of a cross section of each one of the plurality of third conductive vias.

14. The substrate of claim 13, wherein as for each one of the plurality of seventh conductive vias, a size of the surface close to the first surface is smaller than a size of the surface away from the first surface.

15. The substrate of claim 13, wherein as for each one of the plurality of third conductive vias, a size of the surface close to the first surface is smaller than a size of the surface away from the first surface.

16. The substrate of claim 11, wherein the substrate further comprises:
a third dielectric layer disposed on the second surface of the first dielectric layer;
a plurality of fourth conductive vias penetrating the third dielectric layer; and
a plurality of eighth conductive vias penetrating the third dielectric layer;
wherein the plurality of fourth conductive vias are arranged correspondingly with the plurality of first conductive vias or the plurality of second conductive vias to provide an electrical path, and wherein each one of the plurality of fourth conductive vias has a surface close to the second surface and a surface away from the second surface;
wherein the plurality of eighth conductive vias are arranged correspondingly with the plurality of fifth conductive vias or the plurality of six conductive vias to provide an electrical path, and wherein each one of the plurality of eighth conductive vias has a surface close to the second surface and a surface away from the second surface; and
wherein when being cutting along a plane perpendicular to the first surface, a size of cross section of each one of the plurality of eighth conductive vias is larger than a size of a cross section of each one of the plurality of fourth conductive vias.

17. The substrate of claim 16, wherein as for each one of the plurality of fourth conductive vias, a size of the surface close to the second surface is smaller than a size of the surface away from the second surface.

18. The substrate of claim 16, wherein as for each one of the plurality of eighth conductive vias, a size of the surface close to the second surface is smaller than a size of the surface away from the second surface.

19. A method for manufacturing a substrate, comprising:
providing a first dielectric layer having a first surface and a second surface;
opening a plurality of first through holes penetrating the first dielectric layer, flipping the first dielectric layer and then forming a plurality of second through holes penetrating the first dielectric layer;
filling or coating the plurality of first through holes and the plurality of second through holes to form a plurality of first conductive vias and a plurality of second conductive vias respectively;
wherein each one of the first conductive vias has a surface exposed on the first surface and a surface exposed on the second surface, and wherein a size of the surface exposed on the first surface is larger a size of the surface exposed on the second surface; and wherein
each one of the second conductive vias has a surface exposed on the first surface and a surface exposed on the second surface, and wherein a size of the surface exposed on the first surface is smaller than a size of the surface exposed on the second surface.

20. The method of claim 19, wherein the method further comprises:
disposing a second dielectric layer on the first surface of the first dielectric layer, and simultaneously disposing a third dielectric layer on the second surface of the first dielectric layer;
opening a plurality of third through holes penetrating the second dielectric layer, and simultaneously opening a plurality of fourth through holes penetrating the third dielectric layer;
filling or coating the plurality of third through holes and the plurality of fourth through holes to form a plurality of third conductive vias and a plurality of fourth conductive vias respectively;
wherein each one of the plurality of third conductive vias has a surface close to the first surface and a surface away from the first surface, wherein a size of the surface close to the first surface is smaller than a size of the surface away from the first surface; and
wherein each one of the plurality of fourth conductive vias has a surface close to the second surface and a surface away from the second surface, wherein a size of the surface close to the second surface is smaller than a size of the surface away from the second surface.
